(19) United States
(12) Patent Application Publication
(10) Pub. No.: US 2014/0009996 A1
(43) Pub. Date: Jan. 9, 2014

(54) STORAGE CONTROL DEVICE, STORAGE DEVICE, INFORMATION PROCESSING SYSTEM, AND PROCESSING METHOD THEREOF

(71) Applicant: Sony Corporation, Tokyo (JP)

(72) Inventors: Ken Ishii, Tokyo (JP); Keiichi Tsutsui, Kanagawa (JP); Kenichi Nakanishi, Tokyo (JP); Hideaki Okubo, Saitama (JP); Yasushi Fujinami, Tokyo (JP); Naohiro Adachi, Tokyo (JP); Tatsuo Shinbashi, Tokyo (JP)

(73) Assignee: Sony Corporation, Tokyo (JP)

(21) Appl. No.: 13/928,472

(22) Filed: Jun. 27, 2013

(30) Foreign Application Priority Data
Jul. 4, 2012 (JP) 2012-150064

(51) Int. Cl. G11C 13/00

(52) U.S. Cl. CPC G11C 13/004; G11C 13/0069
USPC 365/148; 365/189.15

(57) ABSTRACT

There is provided a storage control device including a read processing unit that reads data and inversion state information indicating whether the data is in an inverted state or a non-inverted state from a specific region of a memory cell array that stores the data and the inversion state information with first intensity in association, and a write processing unit that writes data obtained by inverting the data and a state obtained by changing a state indicated by the inversion state information to an opposite state in the specific region with second intensity that is different from the first intensity.

### BACKGROUND

The present disclosure relates to a storage control device. Particularly, this disclosure relates to a storage control device for non-volatile memories, a storage device, an information processing system, a processing method thereof, and a program that instructs a computer to execute the method.

In an information processing system, a DRAM (Dynamic Random Access Memory), or the like is used as a work memory. Such a DRAM is generally a volatile memory, and thus, content stored in the memory is lost when power supply is interrupted. On the other hand, non-volatile memories (NVM: Non-Volatile Memories) have been used in recent years. Such non-volatile memories are broadly divided into flash memories for data access in a large data amount and non-volatile random access memory (NVRAM: Non-Volatile RAM) that can randomly access data in a small data amount at a high speed. Here, as a typical example of flash memories, a NAND-type flash memory can be exemplified. On the other hand, as examples of non-volatile random access memories, a ReRAM (Resistance RAM), a PCRAM (Phase-Change RAM), a MRAM (Magnetoresistive RAM), and the like can be exemplified.

A ReRAM is a non-volatile memory that uses variable resistive elements, it is not necessary for the memory to erase data in units of blocks prior to writing of data, and direct rewriting can be performed only on necessary pages thereof. This point is a difference from a NAND flash memory, or the like, which stores threshold values of a charge storage amount of a floating gate as data. A variable resistive element can record information of 1 bit in two states which are a high resistive state (HRS: High Resistive State) and a low resistive state (LRS: Low Resistive State).

On the other hand, a technology for performing data writing using a higher pulse voltage in order to prolong data retaining power of such a non-volatile memory has been proposed (for example, refer to JP 2009-507327T). According to data writing using such a high pulse voltage, while data retaining power after such writing is prolonged, stress exerted to memory cells also increases, and accordingly, durability is degraded.

### SUMMARY

In the technology of the related art described above, the two available storage characteristics can be differently used by adjusting the intensity of a pulse voltage. However, this technology of the related art is a technique used when a program or erasing is newly executed, and it is not assumed that the characteristics are changed after data writing is performed once.

It is desirable to flexibly change intensity of writing in a non-volatile memory.

According to a first embodiment of the present disclosure, there is provided a storage control device or a storage control method thereof, the storage control device including a read processing unit that reads data and inversion state information indicating whether the data is in an inverted state or a non-inverted state from a specific region of a memory cell array that stores the data and the inversion state information with first intensity in association, and a write processing unit that writes data obtained by inverting the data and a state obtained by changing a state indicated by the inversion state information to an opposite state in the specific region with second intensity that is different from the first intensity. Accordingly, an effect that intensity of writing in a non-volatile memory is changed while maintaining a logical state of data is attained.

According to the first embodiment of the present disclosure, the memory cell array may be a variable resistive element. The first intensity may be normal intensity indicating one of a high resistive state in which resistance is higher than a predetermined threshold value and low resistive state in which resistance is lower than the predetermined threshold value. The second intensity may be intensity indicating, with regard to the high resistive state, a resistive state in which resistance is higher than resistance in the high resistive state of the first intensity, and indicating, with regard to the low resistive state, a resistive state in which resistance is lower than resistance in the low resistive state of the first intensity. Accordingly, an effect of enhancing a characteristic of holding data of the variable resistive element is attained.

According to the first embodiment of the present disclosure, the memory cell array may be a variable resistive element. The second intensity may be normal intensity indicating one of a high resistive state in which resistance is higher than a predetermined threshold value and a lower resistive state in which resistance is lower than the predetermined threshold value. The first intensity may be intensity indicating, with regard to the high resistive state, a resistive state in which resistance is higher than resistance in the high resistive state of the second intensity, and indicating, with regard to the low resistive state, a resistive state in which resistance is lower than resistance in the low resistive state of the second intensity. Accordingly, an effect of enhancing durability of the variable resistive element is attained.

According to the first embodiment of the present disclosure, the memory cell array may store intensity information indicating whether the data is stored with the first intensity or the second intensity in association with the data. The read processing unit may read the intensity information together with the data. The write processing unit may perform writing of the data obtained by inverting the data and the state obtained by changing the state indicated by the inversion state information to the opposite state in the specific region with the second intensity when the intensity information indicates that the data is stored with the first intensity, and may not perform the writing when the intensity information indicates that data is stored with the second intensity. Accordingly, an effect of controlling a change in intensity of writing according to the intensity information is attained.

According to the first embodiment of the present disclosure, the write processing unit may perform writing of the data obtained by inverting the data and information indicating the inverted state as the inversion state information in the specific region with the second intensity when the inversion state information indicates the non-inverted state, and may not perform the writing when the inversion state information indicates the inverted state. Accordingly, an effect of controlling a change in intensity of writing according to the inversion state information is attained.

According to a second embodiment of the present disclosure, there is provided a storage device including a memory cell array that stores data and inversion state information indicating whether the data is in an inverted state or a non-inverted state in association, a read processing unit that reads the data and the inversion state information from a specific region of the memory cell array that stores the data and the inversion state information are stored with first intensity, and a write processing unit that writes data obtained by inverting the data and a state obtained by changing a state indicated by the inversion state information to an opposite state in the specific region with second intensity that is different from the first intensity. Accordingly, an effect of changing intensity of writing in a non-volatile memory while maintaining a logical state of data is attained.

According to a third embodiment of the present disclosure, there is an information processing system including a memory cell array that stores data and inversion state information indicating whether the data is in an inverted state or a non-inverted state in association, a host computer that issues a command for changing storage intensity to the memory cell array, a read processing unit that reads the data and the inversion state information from a specific region of the memory cell array that stores the data and the inversion state information with first intensity in response to the command, and a write processing unit that writes data obtained by inverting the data and a state obtained by changing a state indicated by the inversion state information to an opposite state in the specific region with second intensity that is different from the first intensity. Accordingly, an effect of changing intensity of writing in a non-volatile memory while maintaining a logical state of data according to the command for changing the storage is attained.

According to the embodiments of the present technology described above, the excellent effect of flexibly changing intensity of writing in a non-volatile memory can be attained.

### BRIEF DESCRIPTION OF THE DRAWINGS

FIG. 1 is a diagram showing an overall configuration example of an information processing system according to an embodiment of the present technology;

FIG. 2 is a diagram showing a configuration example of a non-volatile memory 300 according to an embodiment of the present technology;

FIG. 3 is a diagram showing a field configuration example of each page of a memory cell array 310 according to a first embodiment of the present technology;

FIG. 4 is a graph for describing a set operation of a variable resistive element;

FIG. 5 is a graph for describing a reset operation of a variable resistive element;

FIG. 6 is a graph for describing a strong set operation of a variable resistive element;

FIG. 7 is a graph for describing a strong reset operation of a variable resistive element;

FIG. 8 is a flowchart showing an example of the procedure of a write process of the non-volatile memory 300 according to an embodiment of the present technology;

FIG. 9 is a flowchart showing an example of the procedure of a change process to a strong write state of the non-volatile memory 300 according to the first embodiment of the present technology;

FIG. 10 is a flowchart showing an example of the procedure of a change process to a normal write state of the non-volatile memory 300 according to the first embodiment of the present technology;

FIG. 11 is a flowchart showing an example of the procedure of a read process of the non-volatile memory 300 according to an embodiment of the present technology;

FIG. 12 is a diagram showing a field configuration example of each page of the memory cell array 310 according to a second embodiment of the present technology;

FIG. 13 is a flowchart showing an example of the procedure of a change process to a strong write state of the non-volatile memory 300 according to the second embodiment of the present technology; and

FIG. 14 is a flowchart showing an example of the procedure of a change process to a normal write state of the non-volatile memory 300 according to the second embodiment of the present technology.

### DETAILED DESCRIPTION OF THE EMBODIMENT(S)

Hereinafter, preferred embodiments of the present disclosure will be described in detail with reference to the appended drawings. Note that, in this specification and the appended drawings, structural elements that have substantially the same function and structure are denoted with the same reference numerals, and repeated explanation of these structural elements is omitted.

Hereinafter, embodiments for implementing the present technology (hereinafter, referred to as embodiments) will be described. Description will be provided in the following order.

1. First embodiment (Example in which an inversion flag and a strong write flag are used)

2. Second embodiment (Example in which an inversion flag doubles as a strong write flag)

3. Modified example (Example in which a size is designated)

### 1. First Embodiment

### [Configuration of Information Processing System]

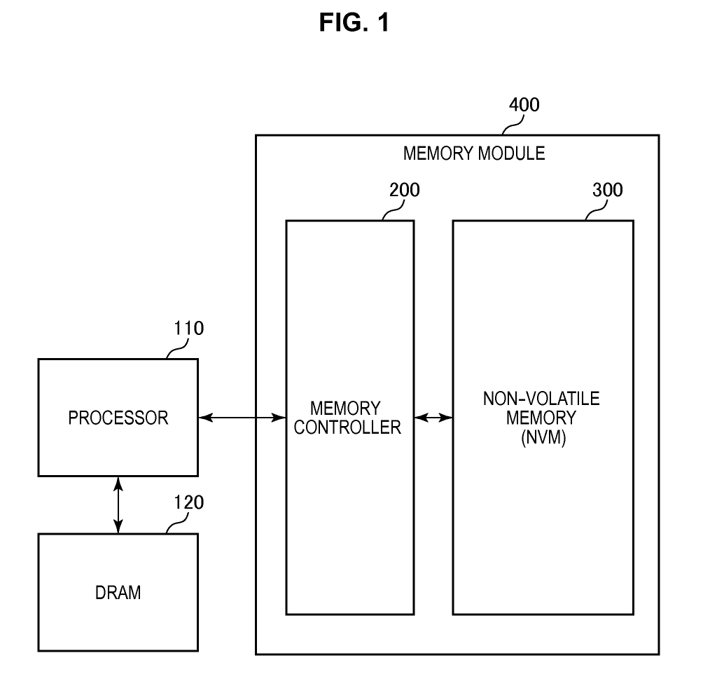

FIG. 1 is a diagram showing an overall configuration example of an information processing system according to an embodiment of the present technology. This information processing system includes a processor 110, a DRAM 120, a non-volatile memory (NVM) 300, and a memory controller 200. The non-volatile memory 300 and the memory controller 200 are included a memory module 400. The memory module 400 is an example of a storage device described in the claims. In addition, the processor 110 is an example of a host computer described in the claims.

The processor 110 is a processing device that conducts information processing by executing various programs. This processor 110 executes programs by repeating loading or storing of data using storage areas of the DRAM 120 as work areas. In addition, the processor 110 accesses various kinds of data stored in the NVM 300 via the memory controller 200.

The DRAM 120 is a volatile memory that functions as a main storage device of the processor 110. This DRAM 120 stores data necessary for the processor 110 executing programs.

The non-volatile memory 300 is a non-volatile memory that functions as an auxiliary storage device of the processor 110. This non-volatile memory 300 is accessed by control of the memory controller 200. The non-volatile memory 300 may be configured by a flash memory, or by a non-volatile random access memory (NVRAM). This non-volatile memory 300 can be applied to both an SnD (Store and Download) model and an XIP (eXecute In Plane) model. In the SnD model, the processor 110 access data stored in the non-volatile memory 300 via the DRAM 120. Thus, the data stored in the non-volatile memory 300 is transferred to the DRAM 120 first, and then accessed as a memory space. On the other hand, in the XIP model, data stored in the non-volatile memory 300 can be accessed as a memory space of the processor 110 without change. In the XIP model, the DRAM 120 itself may be omitted by allowing the non-volatile memory 300 to cover the role of the DRAM 120.

The memory controller 200 controls the non-volatile memory 300, and connects the processor 110 and the non-volatile memory 300. The memory controller 200 has a data buffer for transferring data between the non-volatile memory 300. This data buffer may be realized as an external memory device of the memory controller 200, or as an internal memory.

### [Configuration of Non-Volatile Memory]

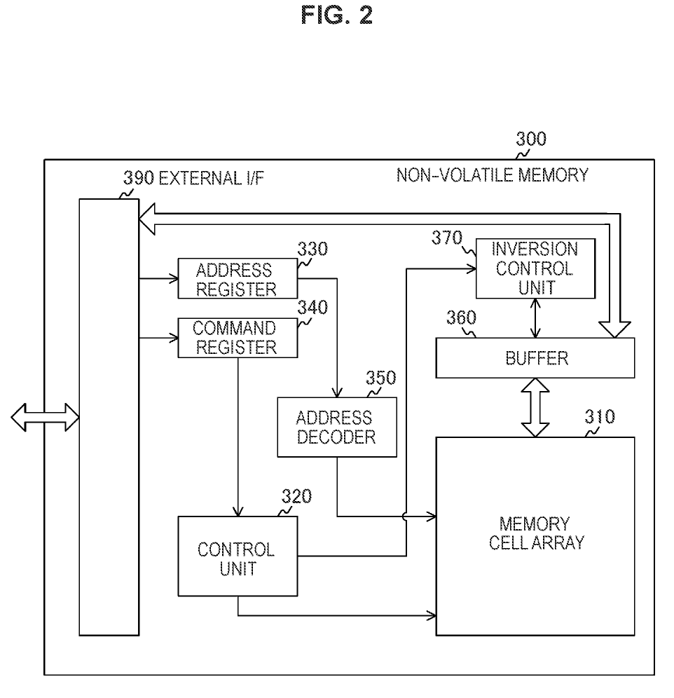

FIG. 2 is a diagram showing a configuration example of the non-volatile memory 300 according to an embodiment of the present technology. This non-volatile memory 300 includes a memory cell array 310, a control unit 320, an address register 330, a command register 340, an address decoder 350, a buffer 360, an inversion control unit 370, and an external interface (I/F) 390.

The memory cell array 310 is an array in which memory cell arrays that retain a predetermined state of each bit are arranged in a grid shape. The memory cell arrays of the memory cell array 310 form a resistance change memory configured by variable resistive elements. A variable resistive element can record information of 1 bit in two states, which are a high resistive state (HRS: High Resistive State) and a low resistive state (LRS: Low Resistive State). Association of either resistive state with either state of “0” or “1” is arbitrary, but description will hereinafter be provided by setting a logic state of the HRS to “1” and a logic state of the LRS to “0.”

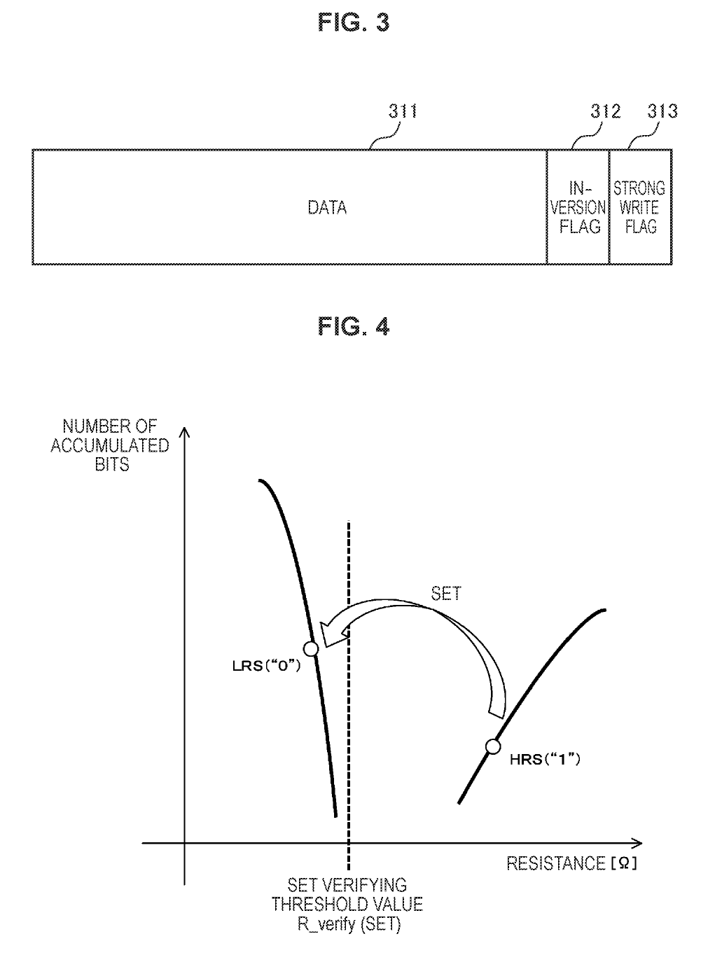

The memory cell array 310 includes a plurality of pages. In each page, data 311, an inversion flag 312, and a strong write flag 313 are recorded as shown in FIG. 3. With regard to the data 311, for example, 32-bit data is assumed as data of one word.

The inversion flag 312 indicates whether or not the corresponding data 311 is stored in an inverted state in the memory cell array 310. Association of the inversion flag 312 with either state of “0” or “1” is also arbitrary. For example, if the data 311 is stored in a non-inverted state, the inversion flag 312 can be cleared to be “0” and if the data 311 is stored in an inverted state, the inversion flag can be asserted to be “1”. This inversion flag 312 is an example of inversion state information described in the claims. It should be noted that, with regard to the inversion flag 312, 1 bit of the inversion flag 312 is sufficient for one data piece 311 logically, but it may be designed to have a plurality of bits in order to enhance reliability.

The strong write flag 313 indicates whether or not the corresponding data 311 is stored in a strong write state in the memory cell array 310. The strong write state is a state of resistance of which the level is higher than a normal state in the case of the high resistive state (strong HRS), and is a state of resistance of which the level is lower than a normal state in the case of the low resistive state (strong LRS), as will be described below. Association of the strong write flag 313 with either state of “0” or “1” is also arbitrary. For example, if the data 311 is not stored in a strong write state, the strong write flag 313 can be cleared to be “0,” and if the data 311 is stored in a strong write state, the strong write flag 313 can be asserted as “1.” This strong write flag 313 is an example of intensity information described in the claims. It should be noted that, with regard to the strong write flag 313, 1 bit of the strong write flag 313 is sufficient for one data piece 311 logically, but it may be designed to have a plurality of bits in order to enhance reliability.

The control unit 320 is a controller that controls each block included in the non-volatile memory 300. This control unit 320 receives commands from the command register 340, and outputs control signals to the memory cell array 310. In addition, the control unit 320 outputs control signals to the inversion control unit 370 so as to control data inversion or non-inversion of the buffer 360. It should be noted that the control unit 320 is an example of a read processing unit or a write processing unit described in the claims.

The address register 330 is a register that receives write addresses or read addresses instructed by the external I/F 390 and then temporarily retains the addresses. Addresses retained in the address register 330 are supplied to the address decoder 350.

The command register 340 is a register that receives commands instructed by the external I/F 390 and then temporarily retains the addresses. Commands retained in the command register 340 are supplied to the control unit 320. As commands retained in the command register 340, for example, write commands for instructing writing of write data in the memory cell array 310 and read commands for instructing reading of read data from the memory cell array 310 are assumed. In addition, in the present embodiment, a change command for changing the normal write state to the strong write state and a change command for changing the strong write state to the normal write state are also included.

The address decoder 350 decodes addresses supplied from the address register 330, and sets page regions of the memory cell array 310 corresponding to the addresses as access targets.

The buffer 360 is a buffer for page regions of the memory cell array 310 when accessing. For example, write data that is a writing target on the memory cell array 310 during write access is retained therein. In addition, read data that is read from the memory cell array 310 during read access is retained therein. This buffer 360 also retains the inversion flag 312 and the strong write flag 313 corresponding to the data 311 as shown in FIG. 3.

The inversion control unit 370 instructs the buffer 360 to inversion retained data according to an instruction from the control unit 320. It should be noted that this inversion control unit 370 is an example of a write processing unit described in the claims.

The external interface 390 is an interface for data exchange with the memory controller 200.

### [State Transition of Variable Resistive Element]

FIG. 4 is a graph for describing a set operation of a variable resistive element. As described above, the variable resistive element is set to be in either of the two states of the high resistive state (HRS) and the low resistive state (LRS). If the horizontal axis of the graph indicates resistance values and the vertical axis thereof indicates the relative number of accumulated bits, distribution of the resistance values is divided into a low-value portion and a high-value portion. The portion of low resistance values is in the LRS, and the portion of high resistance values is in the HRS. As shown in the graph, an operation of state transition from the HRS to the LRS by causing a current to flow in memory cells is called a set operation. In this case, in order to verify whether or not the set operation is completed normally after the set operation is performed, a set verifying threshold value R_verify (set) provided on the low resistance side rather than the center of both distributions is used. When the verification fails, the set operation is attempted again.

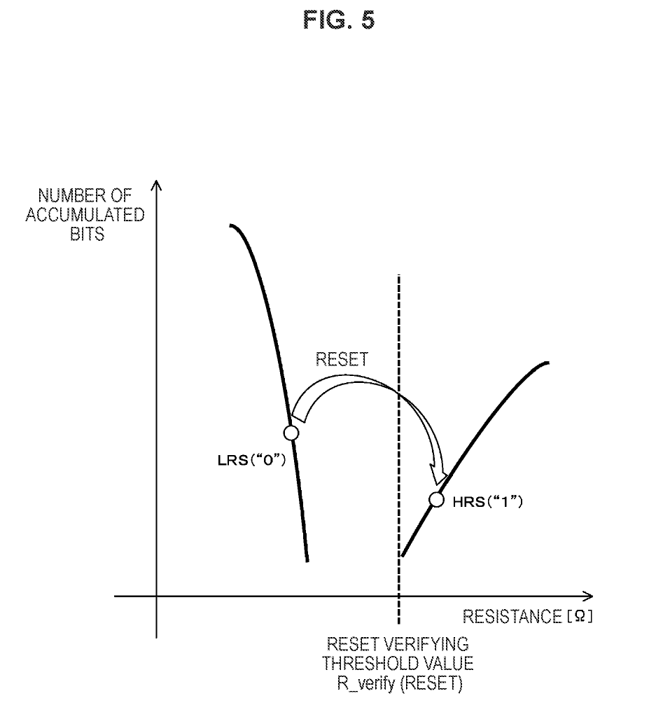

FIG. 5 is a graph for describing a reset operation of a variable resistive element. As shown in the graph, an operation of state transition from the LRS to the HRS by causing a current to flow in memory cells in the direction opposite to the direction of the set operation is called a reset operation. In this case, in order to verify whether or not the reset operation is completed normally after the reset operation is performed, a reset verifying threshold value R_verify (reset) provided on the high resistance side rather than the center of both distributions is used. When the verification fails, the reset operation is attempted again.

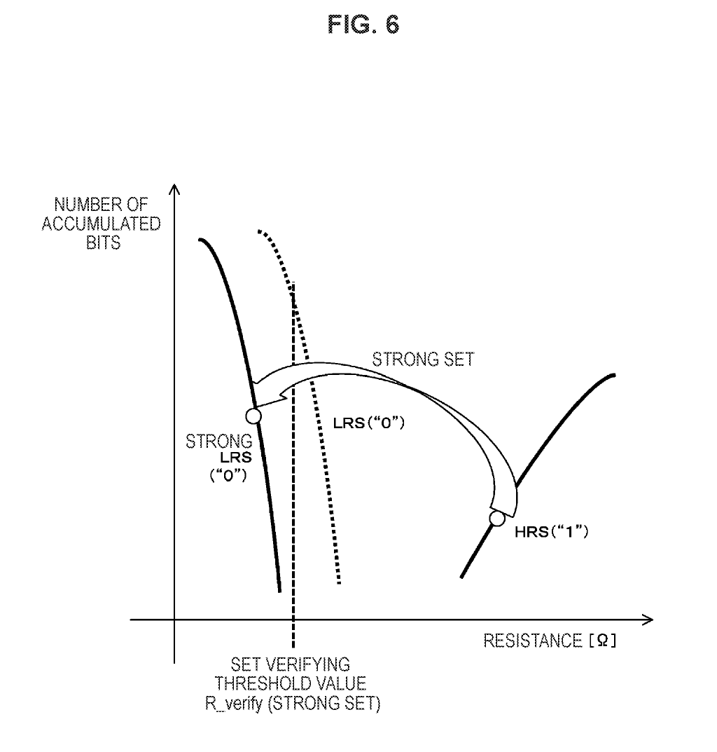

FIG. 6 is a graph for describing a strong set operation of a variable resistive element. As described above, in a variable resistive element, a write state of which resistance is stronger than usual can occur in both states of the HRS and the LRS. The graph shows a strong LRS when a resistive state is set to be a lower resistive state than in the LRS. This strong LRS is realized by further expanding the size or the width of an applied voltage pulse during setting than in a normal set operation. In this case, in order to verify whether or not the strong set operation is completed normally after the strong set operation is performed, a strong set verifying threshold value R_verify (strong set) provided on the low resistance side rather than the set verifying threshold value is used. When this verification fails, the strong set operation is attempted again.

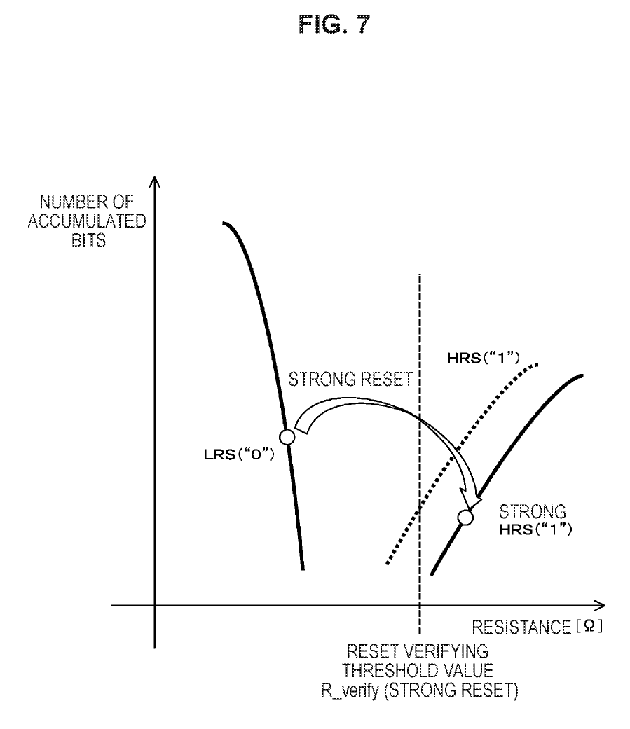

FIG. 7 is a graph for describing a strong reset operation of a variable resistive element. This graph shows a strong HRS when a resistive state is set to be a higher resistive state than in the HRS. This strong HRS is realized by further expanding the size or the width of an applied voltage pulse during resetting than in a normal reset operation. In this case, in order to verify whether or not the strong reset operation is completed normally after the strong reset operation is performed, a strong reset verifying threshold value R_verify (strong reset) provided on the high resistance side rather than the reset verifying threshold value is used. When this verification fails, the strong reset operation is attempted again.

The strong LRS and the strong HRS resulting from the strong set operation and the strong reset operation are collectively called a strong write state. In the memory cells in the strong write state, since resistance values are not easily inverted in comparison to the HRS or the LRS resulting from a normal set operation or reset operation, the data retaining characteristic can be prolonged. On the other hand, since stress exerted on the memory cells in the strong write state increases, and durability is degraded, there are cases of a resistive state returning to normal write state.

In order to set to be in the strong write state, transition from the HRS to the strong LRS, or from the LRS to the strong HRS is necessary. On the other hand, in order to return to the normal write state from the strong write state, transition from the strong HRS to the LRS, or from the strong LRS to the HRS is necessary. In other words, in order to make a state change between the strong write state to the normal write state, an operation of transition to a different state from the current state in the two states of the HRS and the LRS is necessary. For this reason, if a state change is made between the strong write state and the normal write state without changing the logic state of “0” or “1,” two operations including setting and resetting are necessary in a technique of the related art. Thus, in this embodiment, when a state change is made between the strong write state and the normal write state, interpretation of a logic state is inverted by reversing the content of the inversion flag 312, and accordingly, the number of set or reset operations can be suppressed to be performed once.

### [Operation of Non-Volatile Memory]

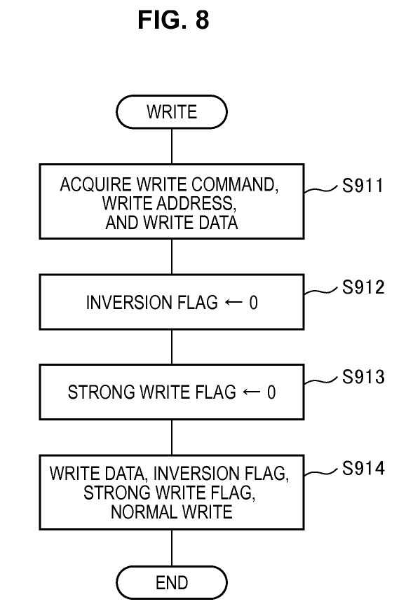

FIG. 8 is a flowchart showing an example of the procedure of a write process of the non-volatile memory 300 according to an embodiment of the present technology.

When a write command is issued from the processor 110, the write command is retained in the command register 340, a write address is retained in the address register 330, and write data is retained in the buffer 360 (Step S911).

Then, the inversion control unit 370 clears an inversion flag of the buffer 360 to be “0” indicating a non-inversion state (Step S912). In addition, the inversion control unit 370 clears a strong write flag of the buffer 360 to be “0” indicating a state in which data is not stored in a strong write state (Step S913).

After that, the write data, the inversion flag, and the strong write flag prepared in the buffer 360 as described above are written in the memory cell array 310 in the normal write state (Step S914). In this case, memory cells on which the data is written are in either state of the HRS or the LRS.

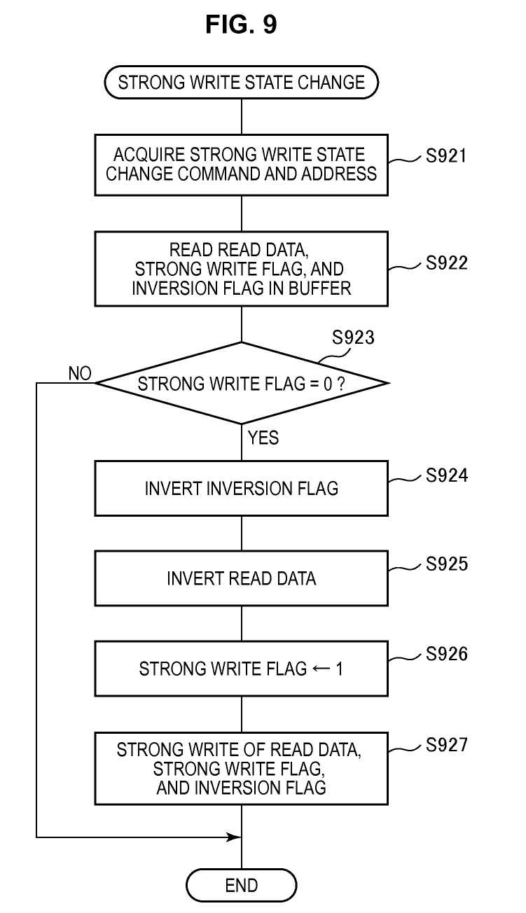

FIG. 9 is a flowchart showing an example of the procedure of a change process to the strong write state of the non-volatile memory 300 according to the first embodiment of the present technology.

When a change command to the strong write state is issued from the processor 110, a strong write state change command is retained in the command register 340, and a change target address is retained in the address register 330 (Step S921).

Then, data reading is performed from a region of the memory cell array 310 corresponding to the change target address, and the data is retained in the buffer 360 (Step S922). In other words, the buffer 360 retains read data, an inversion flag, and a strong write flag. In this case, when the strong write flag retained in the buffer 360 is cleared to be “1” indicating a state in which the data is stored in a strong write state (Step S923: No), the change process to the strong write state ends. On the other hand, when the strong write flag retained in the buffer 360 is cleared to be “0” indicating a state in which the data is not stored in a strong write state (Step S923: Yes), the following process continues.

The inversion control unit 370 inversions the content of the inversion flag retained in the buffer 360 (Step S924). In addition, the inversion control unit 370 inversions the read data stored in the buffer 360 (Step S925). Furthermore, the inversion control unit 370 asserts the strong write flag retained in the buffer 360 to be “1” indicating a state in which data is stored in the strong write state.

After that, the read data, the inversion flag, and the strong write flag prepared in the buffer 360 in that manner are written in the memory cell array 310 in the strong write state (Step S927). In this case, memory cells in which data is written are in either state of the strong HRS or the strong LRS, i.e. the strong write state.

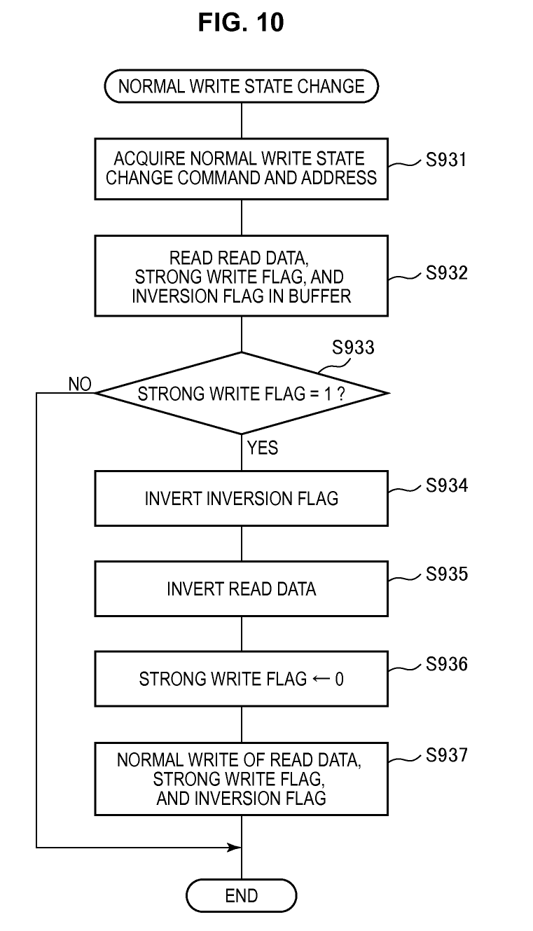

FIG. 10 is a flowchart showing an example of the procedure of a change process to the normal write state of the non-volatile memory 300 according to the first embodiment of the present technology.

When a change command to the normal write state is issued from the processor 110, the change command to the normal write state is retained in the command register 340, and a change target address is retained in the address register 330 (Step S931).

Then, data reading is performed from a region corresponding to the change target address of the memory cell array 310, and then the data is retained in the buffer 360 (Step S932). In other words, the buffer 360 retains the read data, an inversion flag, and a strong write flag. In this case, if the strong write flag retained in the buffer 360 is cleared to be “0” indicating that data is not stored in the strong write state (Step S933: No), the change process to the normal write state ends. On the other hand, if the strong write flag retained in the buffer 360 is asserted to be “1” indicating that data is stored in the strong write state (Step S933: Yes), the following process continues.

The inversion control unit 370 inversions the content of the inversion flag retained in the buffer 360 (Step S934). In addition, the inversion control unit 370 inversions the read data retained in the buffer 360 (Step S935). Furthermore, the inversion control unit 370 clears the strong write flag retained in the buffer 360 to be “0” indicating the state in which data is not stored in the strong write state (Step S936).

After that, the read data, the inversion flag, and the strong write flag prepared in the buffer 360 in this manner are written in the memory cell array 310 in the normal write state (Step S937). In this case, memory cells in which the data is written are in either state of the HRS or the LRS, i.e., the normal write state.

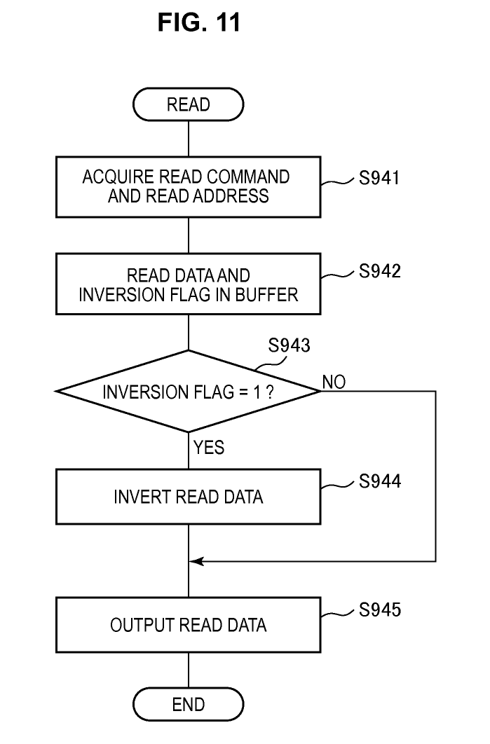

FIG. 11 is a flowchart showing an example of the procedure of a read process of the non-volatile memory 300 according to an embodiment of the present technology.

When a read command is issued from the processor 110, the read command is retained in the command register 340, and a read address is retained in the address register 330 (Step S941).

Then, data reading from a region corresponding to the read address of the memory cell array 310 is performed, and then the data is retained in the buffer 360 (Step S942). In other words, the buffer 360 retains read data and an inversion flag. It should be noted that, in the read process, a strong write flag is not necessary at all times, but may be read by the buffer 360 at the same time.

At this moment, if the inversion flag retained in the buffer 360 is asserted to be “1” indicating the state that the data is inverted (Step S943: Yes), the inversion control unit 370 inversions the read data retained in the buffer 360 (Step S944). On the other hand, if the inversion flag retained in the buffer 360 is cleared to be “0” indicating the state in which the data is not inverted (Step S943: No), the read data is not inverted.

After that, the read data prepared in the buffer 360 in this manner is output to the memory controller 200 via the external I/F 390 (Step S945).

In this manner, according to the first embodiment, when a state change is made between the strong write state and the normal write state, interpretation of a logic state is inverted by reversing the content of the inversion flag 312, and thereby the number of set or reset operations can be suppressed to be once. In other words, when a state change is made between the strong write state and the normal write state, the number of writings in memory cells can be halved. In addition, when a state change is made between the strong write state and the normal write state, reception of data from the memory controller 200 is not accompanied, and thus, a quick state change can be realized.

### 2. Second Embodiment

In the first embodiment described above inversion control and intensity control are performed using both an inversion flag and a strong write flag, but in the second embodiment, control is simplified by assigning the function of the strong write flag to the inversion flag. It should be noted that the overall configuration of the information processing system and the configuration of the non-volatile memory 300 are the same as those described referring to FIGS. 1 and 2.

### [Configuration of Non-Volatile Memory]

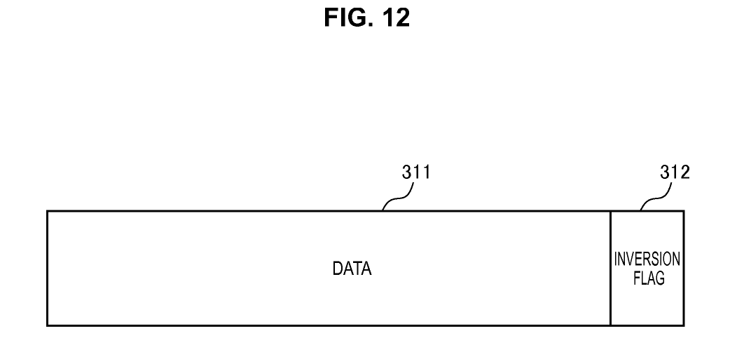

FIG. 12 is a diagram showing a field configuration example of each page of the memory cell array 310 according to the second embodiment of the present technology. In this second embodiment, each page stores the data 311 and the inversion flag 312. In other words, the strong write flag 313 of the first embodiment is configured to be omitted.

In the second embodiment, the inversion flag 312 indicates whether or not the corresponding data 311 is stored in a state of being inverted in the memory cell array 310, and indicates whether or not the data is stored in the strong write state. Also in this case, association of the flag with either state of “0” or “1” is arbitrary. For example, if the data 311 is stored in the no-inverted state, and stored in the strong write state, the inversion flag 312 can be cleared to be “0”. In addition, if the data 311 is stored in an inverted state, and stored in the strong write state, the inversion flag 312 can also be asserted to be “1”. Control only using the inversion flag 312 is possible by setting the inversion flag 312 to be in synchronization with intensity information at all times without using the inversion flag in other applications.

### [Operation of Non-Volatile Memory]

The procedures of write and read processes of the non-volatile memory 300 according to the second embodiment of the present technology are the same as those in the first embodiment described referring to FIGS. 8 and 11.

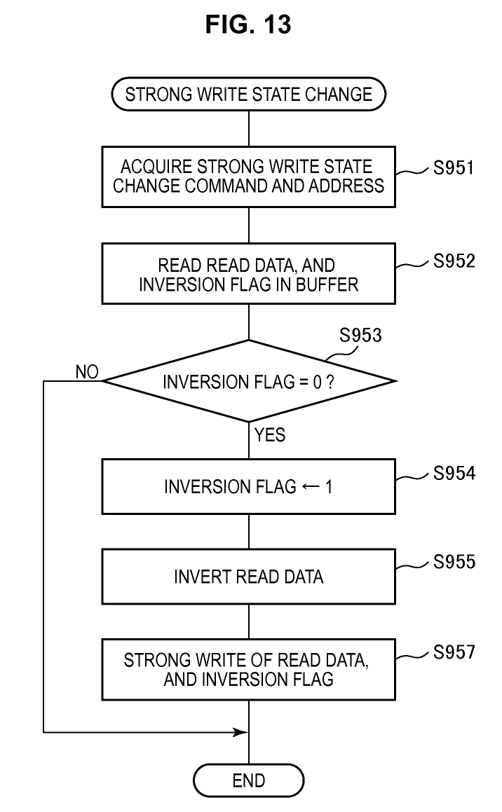

FIG. 13 is a flowchart showing an example of the procedure of a change process to a strong write state of the non-volatile memory 300 according to the second embodiment of the present technology.

When a change command to the strong write state is issued from the processor 110, the change command to the strong write state is retained in the command register 340, and a change target address is retained in the address register 330 (Step S951).

Then, data reading from a region corresponding to the change target address of the memory cell array 310 is performed, and then the data is retained in the buffer 360 (Step S952). In other words, the buffer 360 retains read data and an inversion flag. At this moment, if the inversion flag retained in the buffer 360 is asserted to be “1” indicting the state in which the data is stored in the strong write state (Step S953: No), the change process to the strong write state ends. On the other hand, if the inversion flag retained in the buffer 360 is cleared to be “0” indicating the state in which the data is not stored in the strong write state (Step S953: Yes), the following process continues.

The inversion control unit 370 inversions the content of the inversion flag retained in the buffer 360 to “1” (Step S954). Accordingly, the data 311 turns to indicate to be stored in an inverted state and stored in the strong write state. In addition, the inversion control unit 370 inversions the read data stored in the buffer 360 (Step S955).

After that, the read data, and the inversion flag prepared in the buffer 360 in that manner are written in the memory cell array 310 in the strong write state (Step S957). In this case, memory cells in which the data is written are in either state of the strong HRS or the strong LRS, i.e., the strong write state.

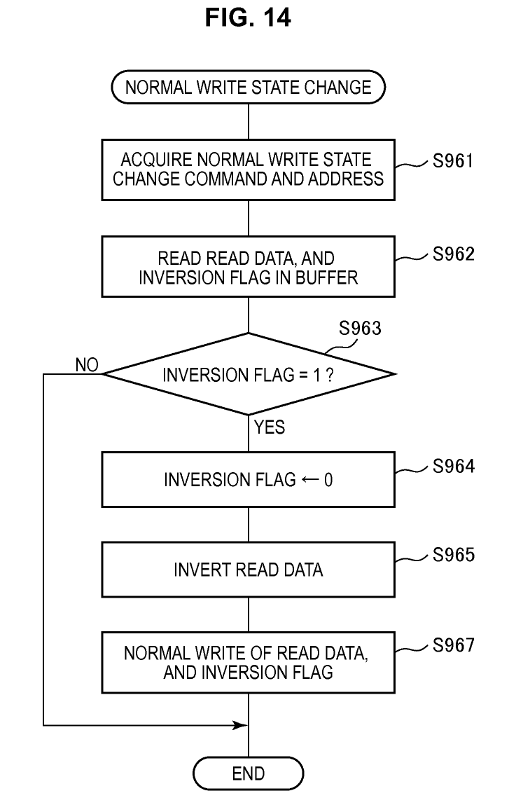

FIG. 14 is a flowchart showing an example of the procedure of a change process to a normal write state of the non-volatile memory 300 according to the second embodiment of the present technology.

When a change command to the normal write process is issued from the processor 110, the change command to the normal write process is retained in the command register 340, and a change target address is retained in the address register 330 (Step S961).

Then, data reading from a region corresponding to the change target address of the memory cell array 310 is performed, and then the data is retained in the buffer 360 (Step S962). In other words, read data and an inversion flag are retained in the buffer 360. At this moment, if the inversion flag retained in the buffer 360 is cleared to be “0” indicating the state in which the data is not stored in the strong write state (Step S963: No), the change process to the normal write state ends. On the other hand, if the inversion flag retained in the buffer 360 is asserted to be “1” indicating the state in which the data is stored in the strong write state (Step S963: Yes), the following process continues.

The inversion control unit 370 inversions the content of the inversion flag retained in the buffer 360 to “0” (Step S964). Accordingly, the data 311 turns to indicate to be stored in a no-inverted state, and to be stored in the normal write state. In addition, the inversion control unit 370 inversions the read data retained in the buffer 360 (Step S965).

After that, the read data and the inversion flag prepared in the buffer 360 in that manner are written in the memory cell array 310 in the normal write state (Step S967). In this case, memory cells in which the data is written are in either state of the HRS or the LRS, i.e., the normal write state.

In this manner, according to the second embodiment of the present technology, inversion control and write intensity control can be simplified by assigning the function of the strong write flag to the inversion flag.

### 3. Modified Example

### [Process on a Plurality of Pages]

In the first and the second embodiments described above, it is assumed that only a page corresponding to a designated address is the target of a write state change process, but a plurality of pages may be set to be processing targets. In this case, it is considered that, by designating the size of change targets (the number of pages) together with a strong write state change command and a normal write state change command, data writing in the memory cell array 310 is performed as many times as the number of pages based on designated addresses, and thereby the write state is changed. Accordingly, the write states of consecutive regions can be set to be changed.

### [Refresh Operation]

In the first and the second embodiments described above, transition between the strong write state and the normal write state is assumed, but transition between a weak write state weaker than the normal write state (hereinafter, referred to as a weak write state) and the normal write state is also considered. Herein, a case in which a long period of time elapses after data writing is performed in the normal write state, causing degraded retaining power, and thereby resulting in the weak write state is assumed. In this case, data in the weak write state is read, the read data is inverted and an inversion flag is inverted, and thereby data writing is performed in the normal write state. Accordingly, the initial retaining power immediately after writing can be regained maintaining the content of the data. In other words, according to this modified example, a refresh operation can be effectively realized.

It should be noted the above-described embodiments are examples to realize the present technology, and items in the embodiments are in a corresponding relationship with invention specific items in the claims. At the same time, the invention specific items in the claims are in a corresponding relationship with items of the embodiments of the present technology to which the same names as those of the invention specific items are given. However, the present technology is not limited to the embodiments, and can be realized by variously modifying the embodiments within the scope of the technology.

In addition, the procedures of the processes described in the embodiments above may be understood as a method that includes a series of the processes, or as a program that instructs a computer to execute the series of the processes and a recording medium in which such a program is stored. As the recording medium, for example, CDs (Compact Discs), MDs (MiniDiscs), DVD (Digital Versatile Disks), memory cards, blu-ray discs (Blu-ray Discs (registered trademark)), and the like can be used.

It should be understood by those skilled in the art that various modifications, combinations, sub-combinations and alterations may occur depending on design requirements and other factors insofar as they are within the scope of the appended claims or the equivalents thereof.

Additionally, the present technology may also be configured as below.

(1) A storage control device including:

a read processing unit that reads data and inversion state information indicating whether the data is in an inverted state or a non-inverted state from a specific region of a memory cell array that stores the data and the inversion state information with first intensity in association; and

a write processing unit that writes data obtained by inverting the data and a state obtained by changing a state indicated by the inversion state information to an opposite state in the specific region with second intensity that is different from the first intensity.

(2) The storage control device according to (1),

wherein the memory cell array is a variable resistive element,

wherein the first intensity is normal intensity indicating one of a high resistive state in which resistance is higher than a predetermined threshold value and low resistive state in which resistance is lower than the predetermined threshold value, and

wherein the second intensity is intensity indicating, with regard to the high resistive state, a resistive state in which resistance is higher than resistance in the high resistive state of the first intensity, and indicating, with regard to the low resistive state, a resistive state in which resistance is lower than resistance in the low resistive state of the first intensity.

(3) The storage control device according to (1),

wherein the memory cell array is a variable resistive element,

wherein the second intensity is normal intensity indicating one of a high resistive state in which resistance is higher than a predetermined threshold value and a lower resistive state in which resistance is lower than the predetermined threshold value, and

wherein the first intensity is intensity indicating, with regard to the high resistive state, a resistive state in which resistance is higher than resistance in the high resistive state of the second intensity, and indicating, with regard to the low resistive state, a resistive state in which resistance is lower than resistance in the low resistive state of the second intensity.

(4) The storage control device according to any one of (1) to (3),

wherein the memory cell array stores intensity information indicating whether the data is stored with the first intensity or the second intensity in association with the data,

wherein the read processing unit reads the intensity information together with the data, and

wherein the write processing unit performs writing of the data obtained by inverting the data and the state obtained by changing the state indicated by the inversion state information to the opposite state in the specific region with the second intensity when the intensity information indicates that the data is stored with the first intensity, and does not perform the writing when the intensity information indicates that data is stored with the second intensity.

(5) The storage control device according to any one of (1) to (3), wherein the write processing unit performs writing of the data obtained by inverting the data and information indicating the inverted state as the inversion state information in the specific region with the second intensity when the inversion state information indicates the non-inverted state, and does not perform the writing when the inversion state information indicates the inverted state.
(6) A storage device including:

a memory cell array that stores data and inversion state information indicating whether the data is in an inverted state or a non-inverted state in association;

a read processing unit that reads the data and the inversion state information from a specific region of the memory cell array that stores the data and the inversion state information are stored with first intensity; and

a write processing unit that writes data obtained by inverting the data and a state obtained by changing a state indicated by the inversion state information to an opposite state in the specific region with second intensity that is different from the first intensity.

(7) An information processing system including:

a memory cell array that stores data and inversion state information indicating whether the data is in an inverted state or a non-inverted state in association;

a host computer that issues a command for changing storage intensity to the memory cell array;

a read processing unit that reads the data and the inversion state information from a specific region of the memory cell array that stores the data and the inversion state information with first intensity in response to the command; and

a write processing unit that writes data obtained by inverting the data and a state obtained by changing a state indicated by the inversion state information to an opposite state in the specific region with second intensity that is different from the first intensity.

(8) A storage control method including:

reading data and inversion state information indicating whether the data is in an inverted state or a non-inverted state from a specific region of a memory cell array that stores the data and the inversion state information with first intensity in association; and

writing that data obtained by inverting the data and a state obtained by changing a state indicated by the inversion state information to an opposite state in the specific region with second intensity that is different from the first intensity.

The present disclosure contains subject matter related to that disclosed in Japanese Priority Patent Application JP 2012-150064 filed in the Japan Patent Office on Jul. 4, 2012, the entire content of which is hereby incorporated by reference.

What is claimed is:

1. A storage control device comprising:
a read processing unit that reads data and inversion state information indicating whether the data is in an inverted state or a non-inverted state from a specific region of a memory cell array that stores the data and the inversion state information with first intensity in association; and
a write processing unit that writes data obtained by inverting the data and a state obtained by changing a state indicated by the inversion state information to an opposite state in the specific region with second intensity that is different from the first intensity.

2. The storage control device according to claim 1,
wherein the memory cell array is a variable resistive element,
wherein the first intensity is normal intensity indicating one of a high resistive state in which resistance is higher than a predetermined threshold value and low resistive state in which resistance is lower than the predetermined threshold value, and
wherein the second intensity is intensity indicating, with regard to the high resistive state, a resistive state in which resistance is higher than resistance in the high resistive state of the first intensity, and indicating, with regard to the low resistive state, a resistive state in which resistance is lower than resistance in the low resistive state of the first intensity.

3. The storage control device according to claim 1,
wherein the memory cell array is a variable resistive element,
wherein the second intensity is normal intensity indicating one of a high resistive state in which resistance is higher than a predetermined threshold value and a lower resistive state in which resistance is lower than the predetermined threshold value, and
wherein the first intensity is intensity indicating, with regard to the high resistive state, a resistive state in which resistance is higher than resistance in the high resistive state of the second intensity, and indicating, with regard to the low resistive state, a resistive state in which resistance is lower than resistance in the low resistive state of the second intensity.

4. The storage control device according to claim 1,
wherein the memory cell array stores intensity information indicating whether the data is stored with the first intensity or the second intensity in association with the data,
wherein the read processing unit reads the intensity information together with the data, and
wherein the write processing unit performs writing of the data obtained by inverting the data and the state obtained by changing the state indicated by the inversion state information to the opposite state in the specific region with the second intensity when the intensity information indicates that the data is stored with the first intensity, and does not perform the writing when the intensity information indicates that data is stored with the second intensity.

5. The storage control device according to claim 1, wherein the write processing unit performs writing of the data obtained by inverting the data and information indicating the inverted state as the inversion state information in the specific region with the second intensity when the inversion state information indicates the non-inverted state, and does not perform the writing when the inversion state information indicates the inverted state.

6. A storage device comprising:
a memory cell array that stores data and inversion state information indicating whether the data is in an inverted state or a non-inverted state in association;
a read processing unit that reads the data and the inversion state information from a specific region of the memory cell array that stores the data and the inversion state information are stored with first intensity; and
a write processing unit that writes data obtained by inverting the data and a state obtained by changing a state indicated by the inversion state information to an opposite state in the specific region with second intensity that is different from the first intensity.

7. An information processing system comprising:
a memory cell array that stores data and inversion state information indicating whether the data is in an inverted state or a non-inverted state in association;
a host computer that issues a command for changing storage intensity to the memory cell array;
a read processing unit that reads the data and the inversion state information from a specific region of the memory cell array that stores the data and the inversion state information with first intensity in response to the command; and
a write processing unit that writes data obtained by inverting the data and a state obtained by changing a state indicated by the inversion state information to an opposite state in the specific region with second intensity that is different from the first intensity.

8. A storage control method comprising:
reading data and inversion state information indicating whether the data is in an inverted state or a non-inverted state from a specific region of a memory cell array that stores the data and the inversion state information with first intensity in association; and
writing that data obtained by inverting the data and a state obtained by changing a state indicated by the inversion state information to an opposite state in the specific region with second intensity that is different from the first intensity.
